(19) United States
(12) Patent Application Publication
(10) Pub. No.: US 2026/0144107 A1
(43) Pub. Date: May 21, 2026

(54) SEMICONDUCTOR PACKAGE

(71) Applicant: Samsung Electronics Co., Ltd., Suwon-si (KR)

(72) Inventor: Hyunsoo CHUNG, Suwon-si (KR)

(21) Appl. No.: 19/370,918

(22) Filed: Oct. 28, 2025

(30) Foreign Application Priority Data
Nov. 15, 2024 (KR) 10-2024-0163426

(51) Int. Cl. H01L 23/538; H01L 23/31; H01L 23/48; H01L 23/49; H01L 23/498; H01L 23/528; H01L 25/03; H01L 25/065; H01L 25/16

(52) U.S. Cl. CPC H10W 70/65; H10W 20/20; H10W 20/43; H10W 70/611; H10W 72/50; H10W 74/131; H10W 90/00; H10W 90/701

(57) ABSTRACT

Provided is a semiconductor package with improved reliability, the semiconductor package including a redistribution substrate, a first chip disposed on an upper surface of the redistribution substrate in a first direction, a bridge die having an upper surface and a lower surface, the lower surface of the bridge die being disposed on the first chip in the first direction, the upper surface of the bridge die being opposite the lower surface, and a second chip disposed on the upper surface of the bridge die in the first direction, and the bridge die includes a first region overlapping the first chip in the first direction, and a second region that does not overlap the first chip in the first direction.

### CROSS-REFERENCE TO RELATED APPLICATIONS

This application claims the benefit of Korean Patent Application No. 10-2024-0163426, filed on Nov. 15, 2024, in the Korean Intellectual Property Office, the disclosure of which is incorporated herein by reference in its entirety.

### BACKGROUND

### 1. Field of the Invention

The present disclosure relates to a semiconductor package.

### 2. Description of the Related Art

With development of electronic industry, a demand for high functionalization, high speed, and miniaturization of an electronic component is increasing. To correspond to such a trend, a method of stacking and mounting multiple semiconductor chips on one package wiring structure or a method of stacking a package on another package may be used. For example, a package-in-package (PIP)-type semiconductor package or a package-on-package (POP)-type semiconductor package may be used.

A plurality of semiconductor chips are mounted as a semiconductor package is highly integrated, and a bridge die that electrically connects the plurality of semiconductor chips is used.

### SUMMARY

An aspect provides a miniaturized semiconductor package.

Another aspect also provides a semiconductor package with improved reliability.

However, the goals to be achieved by example embodiments of the present invention are not limited to the objectives described herein and other objects may be clearly understood from the following example embodiments by those skilled in the art.

According to an aspect, there is provided a semiconductor package including a redistribution substrate, a first chip disposed on an upper surface of the redistribution substrate in a first direction, a bridge die having an upper surface and a lower surface, the lower surface of the bridge die being on the first chip in the first direction, the upper surface of the bridge die being opposite the lower surface, and a second chip on the upper surface of the bridge die in the first direction, and the bridge die includes a first region overlapping the first chip in the first direction, and a second region that does not overlap the first chip in the first direction.

According to another aspect, there is also provided a semiconductor package including a redistribution substrate, a first chip on an upper surface of the redistribution substrate in a first direction, a bridge die having an upper surface and a lower surface, the lower surface of the bridge die being disposed on the first chip in the first direction, the upper surface of the bridge die being opposite the lower surface and a second chip disposed on the upper surface of the bridge die in the first direction, and at least a portion of the first chip and at least a portion of the second chip overlap each other in the first direction.

According to still another aspect, there is also provided a semiconductor package including a redistribution substrate, a first chip disposed on an upper surface of the redistribution substrate in a first direction, a bridge die having an upper surface and a lower surface, the lower surface of the bridge die being disposed on the first chip in the first direction, the upper surface of the bridge die being opposite the lower surface, a second chip disposed on the upper surface of the bridge die in the first direction, a connection die on the first chip in the first direction, wherein the connection die is spaced apart from the bridge die in a second direction crossing the first direction, and a dummy die spaced apart from the second chip in the second direction, wherein the dummy die is on the connection die, and at least a portion of the first chip, at least a portion of the bridge die, and at least a portion of the second chip overlap each other in the first direction, an upper surface of the connection die and the upper surface of the bridge die are disposed on an identical plane, the first chip includes a logic chip, and the second chip includes a memory chip.

Additional aspects of example embodiments will be set forth in part in the description which follows and, in part, will be apparent from the description.

### BRIEF DESCRIPTION OF THE FIGURES

These and/or other aspects, features, and advantages of the invention will become apparent and more readily appreciated from the following description of example embodiments, taken in conjunction with the accompanying drawings of which:

FIG. 1 is an example diagram illustrating a cross section of a semiconductor package according to some example embodiments;

FIG. 2 is an example diagram illustrating an enlargement of portion P of FIG. 1;

FIG. 3 is an example diagram illustrating an enlargement of portion P of FIG. 1 in order to describe a semiconductor package according to some other example embodiments;

FIG. 4 is an example diagram illustrating a cross section of a semiconductor package according to still some other example embodiments;

FIG. 5 is an example diagram illustrating a cross section of a semiconductor package according to still some other example embodiments;

FIG. 6 is an example diagram illustrating a cross section of a semiconductor package according to some example embodiments; and

FIGS. 7 through 10 are example diagrams illustrating intermediate operations for a method for fabricating a semiconductor package according to some example embodiments, for example, as illustrated in FIG. 1.

### DETAILED DESCRIPTION

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and/or the present application, and will not be interpreted in an idealized or overly formal sense unless expressly so defined herein.

In the following descriptions, terms in a singular form include terms in a plural form unless an apparently and contextually conflicting description is present.

Terms such as “including” or “comprising” is to indicate that a feature, a number, an operation, an action, an element, a component, or a combination thereof is present. It should be understood that the terms are not to exclude in advance a possibility that one or more other features, numbers, operations, actions, elements, components, or combinations thereof may be present or added.

It will be understood that when an element is referred to as being “connected” or “connected to” or “on” another element, it can be directly connected to or on the other element or intervening elements may be present. In contrast, when an element is referred to as “contacting” or “in contact with” another element (or using any form of the word “contact”), there are no intervening elements present at the point of contact. As the state of contact is binary (either in contact or not in contact), it will be appreciated that “contact” has the same scope as any use of “direct contact.”

Terms including an ordinal number such as “first” or “second” used in the present specification may be used to describe various elements. However, the elements may not be limited by the terms including the ordinal number. The terms may be used to contextually distinguish one element from another element in a part of the specification. Within the present disclosure, a first element may be referred to as a second element in another part of the specification, and the second element may be referred to as the first element in another part of the specification. Also, in the accompanying drawings, shapes, sizes, or the like of elements in the drawings may be exaggerated for clearer description.

As used herein, items described as being “electrically connected” are configured such that an electrical signal can be passed from one item to the other. Therefore, a passive electrically conductive component (e.g., a wire, pad, internal electrical line, etc.) physically connected to a passive electrically insulative component (e.g., a prepreg layer of a printed circuit board, an electrically insulative adhesive connecting two device, an electrically insulative underfill or mold layer, etc.) is not electrically connected to that component. Moreover, items that are “directly electrically connected,” to each other are electrically connected through one or more passive elements, such as, for example, wires, pads, internal electrical lines, through vias, etc. As such, directly electrically connected components do not include components electrically connected through active elements, such as transistors or diodes. Directly electrically connected elements may be directly physically connected and directly electrically connected. Spatially relative terms, such as “below,” “lower,” “above,” “upper,” “front,” “rear”, and the like, may be used herein for ease of description to describe one element's or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” other elements or features would then be oriented “above” the other elements or features. Thus, the term “below” can encompass both an orientation of above and below. The device may be otherwise oriented (rotated 90 degrees or at other orientations) and the spatially relative descriptors used herein interpreted accordingly.

As used herein the terms “on”, “over”, “cover” or “overlap” are intended to mean that an element is over or aside another element. The elements may be touching or not. For example, there may be layers between layers that are “on” one another. An element that is “on”, “disposed on”, or “over” or “covers” or “overlaps” another element need not cover an entire top surface of an element below to be considered “on” or “over” or “covering” or “overlapping”. The terms are intended to encompass one element “on” or “over” or “covering” or “overlapping” all, or any part of, an element below it.

As used herein, the words “surround”, “surrounded” and “surrounding” are intended to mean that an element is outside the other element. The elements may be touching or not. The surrounding element may or may not completely surround an inner element.

As used herein, a semiconductor device may refer, for example, to a device such as a semiconductor chip (e.g., memory chip and/or logic chip formed on a die), a stack of semiconductor chips, a semiconductor package including one or more semiconductor chips stacked on a package substrate, or a package-on-package device including a plurality of packages. These devices may be formed using ball grid arrays, wire bonding, through substrate vias, or other electrical connection elements, and may include memory devices such as volatile or non-volatile memory devices. Semiconductor packages may include a package substrate, one or more semiconductor chips, and an encapsulant formed on the package substrate and covering the semiconductor chips.

The semiconductor device may be a semiconductor chip. Such a semiconductor chip may be a semiconductor device singulated from (e.g., cut from) a wafer (which wafer may be formed with one base substrate (e.g., a bulk silicon substrate, a bulk germanium substrate, silicon on insulator (SOI), etc.), e.g., or formed with a combination of several component wafers each having a corresponding base substrate).

Hereinafter, the example embodiments of the present disclosure will be described with reference to the drawings.

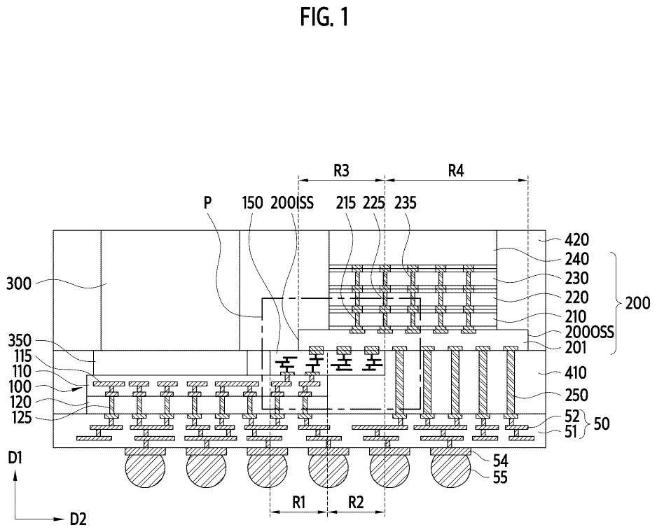

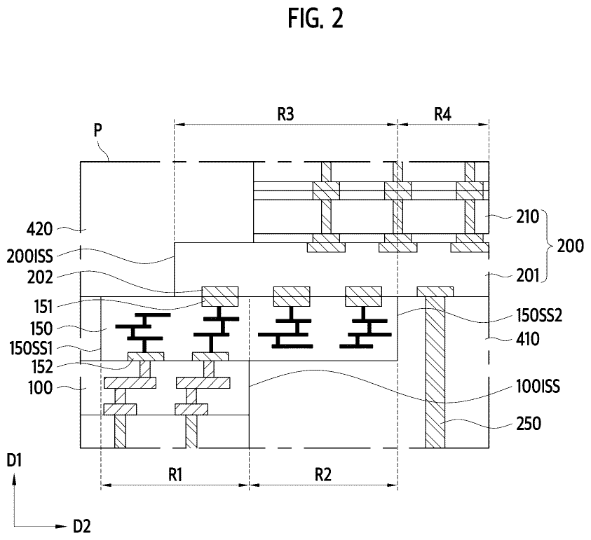

FIG. 1 is an example diagram illustrating a cross section of a semiconductor package according to some example embodiments. FIG. 2 is an example diagram illustrating an enlargement of portion P of FIG. 1.

Referring to FIGS. 1 and 2, the semiconductor package according to some example embodiments may include a redistribution substrate 50, a first chip 100, a bridge die 150, a second chip 200, a wiring post 250, a connection die 350, a dummy die 300, a first molding film 410, and a second molding film 420. As used herein, the term “dummy” is used to refer to a component that has the same or similar structure and shape as other components but does not have a substantial function and exists only as a pattern in the device.

According to some example embodiments, the redistribution substrate 50 may be a wiring structure for a package. For example, the redistribution substrate 50 may be a printed circuit board (PCB), a ceramic substrate, or an interposer. Alternatively, the redistribution substrate 50 may be a wiring structure for a wafer level package (WLP) manufactured at a wafer level.

According to some example embodiments, the redistribution substrate 50 may serve as a redistribution layer. For example, the redistribution substrate 50 may be a front redistribution layer (FRDL) of a fan-out package.

In some example embodiments, the redistribution substrate 50 may be a glass substrate, a ceramic substrate, or a plastic substrate, but these are non-limiting examples. As an example, the redistribution substrate 50 may include a resin (e.g., prepreg, Ajinomoto Build-up Film (ABF), FR-4, or bismaleimide triazine (BT)) impregnated together with an inorganic filler in a core material such as a glass fiber (e.g., a glass cloth or a glass fabric).

According to some example embodiments, the redistribution substrate 50 may include a redistribution insulation film 51 and a redistribution structure 52.

According to some example embodiments, when the redistribution substrate 50 is the printed circuit board, the substrate insulation film 51 may be formed of at least one material selected from a phenolic resin, an epoxy resin, or polyimide. The redistribution substrate 50 may include at least one material selected from tetrafunctional epoxy, polyphenylene ether, epoxy/polyphenylene oxide, bismaleimide triazine (BT), Thermount, cyanate ester, or a liquid crystal polymer.

In some example embodiments, the redistribution insulation film 51 may include a photoimageable dielectric. As an example, the redistribution insulation film 51 may include a photosensitive polymer. The photosensitive polymer may be formed of, for example, at least one of photosensitive polyimide, polybenzoxazole, a phenolic polymer, or a benzocyclobutene-based polymer. As another example, the redistribution insulation film 51 may formed of a silicon oxide film, a silicon nitride film, or a silicon oxynitride film.

According to some example embodiments, the redistribution insulation film 51 may include a stacked plurality of insulation films. FIG. 1 illustrates that the redistribution insulation film 51 as a single film, but the redistribution insulation film 51 may include the plurality of insulation films stacked in a first direction D1. Each insulation film of the plurality of insulation films may surround a wiring pattern and a wiring via of the redistribution structure 52 which will be described below.

According to some example embodiments, a surface of the redistribution insulation film 51 may be covered with solder resist. As an example, a passivation film may be formed on the surface of the redistribution insulation film 51. The passivation film formed on the surface of the redistribution insulation film 51 may protect the redistribution structure 52 and other structures from external impact or moisture. The passivation film may include the solder resist. However, the technical idea of the present invention is not limited thereto.

According to some example embodiments, the redistribution structure 52 may be disposed in the redistribution insulation film 51. The redistribution structure 52 may include a wiring pattern and a wiring via that connects each wiring pattern. For example, the redistribution structure 52 may have a multilayer structure in which two or more wiring patterns or two or more wiring vias are stacked alternately. The wiring pattern may be a portion for horizontal connection between conductive elements, and the wiring via may be a portion for vertical connection between conductive elements. For example, the wiring pattern may be extending in a second direction D2. The wiring via may connect wiring patterns spaced apart in the first direction D1, which may be the vertical direction. The first direction D1 may refer to a direction perpendicular to a surface of the redistribution substrate 50. For example, the first direction D1 may be a direction perpendicular to a lower surface of the redistribution substrate 50 or an upper surface of the redistribution substrate 50. Also, the second direction D2 may cross the first direction D1. The second direction D2 may refer to a direction parallel to the surface of the redistribution substrate 50.

In some example embodiments, the redistribution structure 52 may include a conductive material. For example, the redistribution structure 52 may include copper (Cu), aluminum (Al), silver (Ag), tin (Sn), gold (Au), nickel (Ni), lead (Pb), titanium (Ti), and/or an alloy thereof, but these are non-limiting examples.

According to some example embodiments, an external connection terminal 55 may be formed below the lower surface of the redistribution substrate 50. The external connection terminal 55 may be disposed on an external connection pad 54. The external connection terminal 55 may be in contact with the external connection pad 54. As an example, the external connection terminal 55 may be a solder ball or a solder bump. As another example, the external connection terminal 55 may be a micro bump. The external connection terminal 55 may have a spherical shape or an oval spherical shape, but these are non-limiting examples. The number of external connection terminals 55, an interval between the external connection terminals 55, disposition or a shape of the external connection terminal 55, or the like is not limited to an illustration in any of the present FIGs. and may also vary depending on a design. The external connection terminal 55 may include, for example, tin (Sn), indium (In), bismuth (Bi), antimony (Sb), copper (Cu), silver (Ag), zinc (Zn), lead (Pb), or a combination thereof, but these are non-limiting examples.

According to some example embodiments, the external connection terminal 55 may electrically connect the redistribution structure 52 to an external device. Accordingly, the external connection terminal 55 may provide an electrical signal to the redistribution structure 52 or provide, to the external device, an electrical signal provided from the redistribution structure 52.

For example, the external connection terminal 55 may receive an electric signal for the first chip 100 and the second chip 200. The external connection terminal 55 may receive a signal that is input to the first chip 100 and the second chip 200. The external connection terminal 55 may receive a signal that is output from the first chip 100 and the second chip 200.

According to some example embodiments, the first chip 100 may be disposed on the redistribution substrate 50 in the first direction D1. The first chip 100 may be disposed below the bridge die 150, the second chip 200, the dummy die 300, and the connection die 350. The first chip 100 may be spaced apart from the wiring post 250 in the second direction D2.

According to some example embodiments, the first chip 100 may be an integrated circuit (IC) in which hundreds to millions or more of semiconductor devices are integrated in one chip. As an example, the first chip 100 may be a logic chip. The first chip 100 may be, for example, a microprocessor, an analog element, a digital signal processor, or an application processor. For example, the first chip 100 may be a central processing unit (CPU), a graphic processing unit (GPU), a field-programmable gate array (FPGA), the digital signal processor, an encryption processor, the microprocessor, or the application processor (AP) such as a microcontroller. As another example, the first chip 100 may be a memory chip such as a volatile memory (e.g., a dynamic random access memory (DRAM)) or a non-volatile memory (e.g., a read-only memory (ROM) or a flash memory).

According to some example embodiments, the first chip 100 may include a device layer 110, a first chip substrate 120, and a first through via 125. For example, the device layer 110 and the first chip substrate 120 may be disposed in the first direction D1. FIG. 1 illustrates an example in which the device layer 110 is disposed on the first chip substrate 120. For example, the device layer 110 may be disposed below the first chip substrate 120.

According to some example embodiments, the first chip substrate 120 may be, as an example, bulk silicon or silicon-on-insulator (SOI). As another example, the first chip substrate 120 may be a silicon substrate. As still another example, the first chip substrate 120 may include silicon germanium, silicon germanium on insulator (SGOI), indium antimonide, lead telluride, indium arsenide, gallium arsenide, and/or gallium antimonide.

According to some example embodiments, the first chip substrate 120 may include a conductive region, for example, a well doped with an impurity or a structure doped with an impurity. The first chip substrate 120 may have various element isolation structures such as the shallow trench isolation (STI) structure.

According to some example embodiments, the device layer 110 may be disposed on the first chip substrate 120. The device layer 110 may include various types of a plurality of semiconductor devices and an inter-layer insulation film. The plurality of semiconductor devices may include one or more types of microelectronic devices selected from, for example, a metal-oxide-semiconductor filed effect transistor (MOFSET) such as a complementary metal-insulator-semiconductor (CMOS) transistor, a system large-scale integration (LSI) device, a flash memory, a DRAM, an SRAM, an EEPROM, a PRAM, an RRAM, an image sensor such as an CMOS imaging sensor (CIS), a micro-electro-mechanical system (MEMS), an active element, a passive element, or the like.

According to some example embodiments, a semiconductor device of the device layer 110 may be electrically connected to the conductive region formed in the first chip substrate 120. The semiconductor device in the device layer 110 may be electrically separated from another neighboring semiconductor device by insulation films. The device layer 110 may include a wiring layer 115 electrically connecting the plurality of semiconductor devices and the conductive region of the first chip substrate 120. An insulation layer for protecting the wiring layer 115 and other structures in the device layer 110 from external impact and moisture may be formed on the device layer 110.

According to some example embodiments, the wiring layer 115 may include a metallic wiring layer and a via plug. For example, the wiring layer 115 may have a multilayer structure in which two or more metallic wiring layers or two or more via plugs are stacked alternately. The wiring layer 115 may include an insulation material. For example, the wiring layer 115 may include copper (Cu), aluminum (Al), silver (Ag), tin (Sn), gold (Au), nickel (Ni), lead (Pb), titanium (Ti), and/or an alloy thereof.

According to some example embodiments, the first through via 125 may penetrate at least a portion of the first chip 100. The first through via 125 may be electrically connected to the redistribution structure 52 of the redistribution substrate 50. The first through via 125 may be extending in the first direction D1. The first through via 125 may electrically connect the bridge die 150 and the redistribution structure 50.

According to some example embodiments, the through via 125 may include, as an example, at least one element selected from aluminum (Al), copper (Cu), nickel (Ni), tungsten (W), platinum (Pt), or gold (Au). As another example, the through via 125 may include at least one of titanium (Ti), titanium nitride (TiN), tantalum (Ta), tantalum nitride (TaN), ruthenium (Ru), cobalt (Co), manganese (Mn), tungsten nitride (WN), nickel (Ni), nickel boride (NiB), copper (Cu), a copper (Cu) alloy such as copper-tin (CuSn), copper-magnesium (CuMg), copper-nickel (CuNi), copper-palladium (CuPd), copper-gold (CuAu), copper-rhenium (CuRe), and copper-tungsten (CuW), tungsten (W), a tungsten (W) alloy, nickel (Ni), ruthenium (Ru), or cobalt (Co), but these are non-limiting examples.

According to some example embodiments, the first chip 100 may be connected to the bridge die 150. The first chip 100 may be electrically connected to the second chip 200 through the bridge die 150. The first chip 100 may send and receive an electrical signal to and from the second semiconductor chip 200 through the bridge die 150. The first chip 100 may at least partially overlap the bridge die 150 in the first direction D1. The first chip 100 may be disposed in the first direction D2 across the connection die 350 and the bridge die 150.

According to some example embodiments, the bridge die 150 may be disposed on the first chip 100 in the first direction D1. For example, a lower surface of the bridge die 150 may be on an upper surface of the first chip 100. The bridge die 150 may be disposed between the first chip 100 and the second chip 200 in the first direction D1. A lower surface of the second chip 200 may be on an upper surface of the bridge die 150. The bridge die 150 may electrically connect the first chip 100 and the second chip 200. The bridge die 150 may include a wiring structure that electrically connects the first chip 100 and the second chip 200.

According to some example embodiments, at least a portion of the bridge die 150 may overlap the first chip 100 in the first direction D1. The bridge die 150 may be disposed to be offset from the first chip 100 at a predetermined interval in the second direction D2. At least a portion of the bridge die 150 may overlap the second chip 200 in the first direction D1. The bridge die 150 may be disposed to be offset from the second chip 200 at a predetermined interval in the second direction D2. The bridge die 150 may be disposed across the first chip 100 and the second chip 200 in the second direction D2.

According to some example embodiments, the bridge die 150 may include a first region R1 and a second region R2. The first region R1 and the second region R2 may be disposed in the second direction D2.

According to some example embodiments, the first region R1 may overlap the first chip 100 in the first direction D1. The first region R1 may be disposed on the first chip 100. The first region R1 may be a partial region of the bridge die 150 in the second direction D2 between a first side surface 150SS1 of the bridge die 150 and an inward side surface 100ISS of the first chip. The first side surface 150SS1 of the bridge die 150 may refer to a side surface of the bridge die 150, which faces the connection die 350. According to some example embodiments, the first side surface 150SS1 of the bridge die 150 may overlap the first chip 100 in the first direction D1. The inward side surface 100ISS of the first chip may refer to a side surface of the first chip 100, which faces the wiring post 250. The inward side surface 100ISS of the first chip may overlap the bridge die 150 in the first direction D1.

According to some example embodiments, the second region R2 may not overlap the first chip 100 in the first direction D1. The second region R2 may be disposed on the first molding film 410. The second region R2 may be a partial region of the bridge die 150 in the second direction D2 between a second side surface 150SS2 of the bridge die 150 and the inward side surface 100ISS of the first chip. The second side surface 150SS2 of the bridge die 150 may refer to a side surface of the bridge die 150, which is disposed opposite to the first side surface 150SS1 in the second direction D2 and faces the wiring post 250. The second side surface 150SS2 of the bridge die 150 may not overlap the first chip 100 in the first direction D1.

According to some example embodiments, the bridge die 150 may include an upper bridge connection pad 151 and a lower bridge connection pad 152. The upper bridge connection pad 151 may be disposed on an upper surface of the bridge die 150. The upper bridge connection pad 151 may face the second chip 200. The upper bridge connection pad 151 may be in contact with a lower connection pad 202 of a buffer die 201. The lower bridge connection pad 152 may be disposed on a lower surface of the bridge die 150. The lower bridge connection pad 152 may face the first chip 100. The lower bridge connection pad 152 may be connected to the wiring layer 115 of the first chip 100. FIGS. 1 and 2 illustrate examples in which the lower bridge connection pad 152 of the bridge die 150 is in contact with the wiring layer 115 of the first chip 100. For example, the first chip 100 may further include a connection pad connected to the wiring layer 115 on an upper surface thereof, and the lower bridge connection pad 152 may be in contact with the connection pad disposed on the upper surface of the first chip 100.

The various pads of a device described herein may be conductive terminals connected to internal wiring of the device, and may transmit signals and/or supply voltages between an internal wiring and/or internal circuit of the device and an external source. For example, chip pads of a semiconductor chip may electrically connect to and transmit supply voltages and/or signals between an integrated circuit of the semiconductor chip and a device to which the semiconductor chip is connected. The various pads may be provided on or near an external surface of the device and may have a planar surface having dimensions greater than wiring (e.g., X-Y horizontal dimensions of a pad are both greater than the width of an internal wiring to which it is connected) to promote an electrical connection to a further terminal, such as a bump or solder ball, and/or an external wiring.

According to some example embodiments, a thermal conductivity of the bridge die 150 may be lower than a thermal conductivity of the connection die 350. Thus, heat transferred from the first chip 100 to the second chip 200 through the bridge die 150 may be less than heat transferred from the first chip 100 to the dummy die 300 through the connection die 350.

According to some example embodiments, the second chip 200 may be disposed on the bridge die 150 in the first direction D1. The second chip 200 may be disposed on the first molding film 410. At least a portion of the second chip 200 may overlap the bridge die 150 in the first direction D1. The second chip 200 may be disposed to be offset from the bridge die 150 at the predetermined interval in the second direction D2.

According to some example embodiments, the second chip 200 may include a third region R3 and a fourth region R4. The third region R3 and the fourth region R4 may be disposed in the second direction D2. A width of the third region R3 in the second direction D2 may be smaller than a width of the fourth region R4. The width of the third region R3 In the second direction D2 may be larger than a width of the second region R2.

According to some example embodiments, the third region R3 may overlap the bridge die 150 in the first direction D1. The third region R3 may be disposed on the bridge die 150. The third region R3 may be a partial region of the second chip 200 in the second direction D2 between an inward side surface 200ISS of the second chip and the second side surface 150SS2 of the bridge die 150. The inward side surface 200ISS of the second chip may refer to a side surface of the second chip 200, which faces the dummy die 300. The inward side surface 200ISS of the second chip may overlap the bridge die 150 in the first direction D1.

According to some example embodiments, the fourth region R4 may not overlap the bridge die 150 in the first direction D1. The fourth region R4 may be disposed on the first molding film 410. The fourth region R4 may be a partial region of the second chip 200 in the second direction D2 between the second side surface 150SS2 of the bridge die 150 and an outward side surface 200OSS of the second chip. The outward side surface 200OSS of the second chip may refer to a side surface of the second chip 200, which is disposed opposite to the inward side surface 200ISS of the second chip in the second direction D2.

FIGS. 1 and 2 illustrate examples in which the inward side surface 200ISS and the outward side surface 200OSS of the second chip are side surfaces of the buffer die 201. For example, when a width of a plurality of memory dies 210, 220, 230, and 240 in the second direction D2 is larger than a width of the buffer die 201, the inward side surface 200ISS and the outward side surface 200OSS of the second chip may be side surfaces of the plurality of memory dies 210, 220, 230, and 240.

According to some example embodiments, the second chip 200 may include the buffer die 201 and the plurality of memory dies 210, 220, 230, and 240. The buffer die 201 and the plurality of memory dies 210, 220, 230, and 240 may be disposed in the first direction D1. The buffer die 201 may be disposed below the plurality of memory dies 210, 220, 230, and 240. The plurality of memory dies 210, 220, 230, and 240 may be disposed above the buffer die 201.

According to some example embodiments, the buffer die 201 may be a logic chip. For example, the buffer die 201 may be a microprocessor, an analog element, a digital signal processor, or an application processor. The buffer die 201 may be connected to the bridge die 150 and the wiring post 250.

According to some example embodiments, the buffer die 201 may include the lower connection pad 202. The lower connection pad 202 may be disposed on a lower surface of the second chip 200. The lower connection pad 202 may be disposed on a lower surface of the buffer die 201. The lower connection pad 202 may be in contact with the upper bridge connection pad 151 of the buffer die 150. The buffer die 201 and the bridge die 150 may be connected by a hybrid bonding scheme in which the lower connection pad 202 and the upper bridge connection pad 151 are in contact with each other.

According to some example embodiments, the plurality of memory dies 210, 220, 230, and 240 may include a first memory die 210, a second memory die 220, a third memory die 230, and a fourth memory die 240. According to some example embodiments, the first memory die 210, the second memory die 220, the third memory die 230, and the fourth memory die 240 may be sequentially stacked above the buffer die 201 in the first direction D1. The plurality of memory dies 210, 220, 230, and 240 may be connected to the bridge die 150 and the redistribution substrate 50 through the buffer die 201.

According to some example embodiments, the plurality of memory dies 210, 220, 230, and 240 may be memory chips of an identical type. As an example, the plurality of memory dies 210, 220, 230, and 240 may be a volatile memory chip such as a dynamic random access memory (DRAM) or static random access memory (SRAM). As another example, the plurality of memory dies 210, 220, 230, and 240 may be a non-volatile memory chip such as a phase-change RAM (PRAM), a magnetoresistive RAM (MRAM), a ferroelectric RAM (FeRAM), or a resistive RAM (RRAM). As still another example, the plurality of memory dies 210, 220, 230, and 240 may be a high bandwidth memory (HBM).

According to some example embodiments, the plurality of memory dies 210, 220, 230, and 240 may include second through vias 215, 225, and 235. The second through vias 215, 225, and 235 may penetrate the first memory die 210, the second memory die 220, and the third memory die 230, respectively. The fourth memory die 240 may not include a corresponding second through via. According to some example embodiments, the plurality of memory dies 210, 220, 230, and 240 may be connected to each other through the second through vias 215, 225, and 235.

According to some example embodiments, the second through vias 215, 225, and 235 may include a barrier film formed on a surface of a pillar shape and a buried conductive layer filling an inside of the barrier film. The barrier film may include at least one of titanium (Ti), titanium nitride (TiN), tantalum (Ta), tantalum nitride (TaN), ruthenium (Ru), cobalt (Co), manganese (Mn), tungsten nitride (WN), nickel (Ni), or nickel boride (NiB), but these are non-limiting examples. The buried conductive layer may include at least one of copper (Cu), a copper (Cu) alloy such as copper-tin (CuSn), copper-magnesium (CuMg), copper-nickel (CuNi), copper-palladium (CuPd), copper-gold (CuAu), copper-rhenium (CuRe), and copper-tungsten (CuW), tungsten (W), a tungsten (W) alloy, nickel (Ni), ruthenium (Ru), or cobalt (Co), but these are non-limiting examples.

According to some example embodiments, the plurality of memory dies 210, 220, 230, and 240 may include an upper pad and a lower pad connected to each of the second through vias 215, 225, and 235. An upper pad of the first memory die 210 and a lower pad of the second memory die 220 may be in contact with each other. An upper pad of the second memory die 220 and a lower pad of the third memory die 230 may be in contact with each other. An upper pad of the third memory die 230 and a lower pad of the fourth memory die 240 may be in contact with each other. The plurality of memory dies 210, 220, 230, and 240 may be connected to each other by a hybrid bonding scheme.

According to some example embodiments, the first chip 100, the bridge die 150, and the second chip 200 may be disposed to be offset from each other in the second direction D2. In FIG. 1, the bridge die 150 may be disposed at a right side of the first chip 100 in the second direction D2. The second chip 200 may be disposed at a right side of the bridge die 150 in the second direction D2.

According to some example embodiments, at least a portion of the third region R3 of the second chip 200 may overlap at least a portion of the first region R1 of the bridge die 150 in the first direction D1. In other words, at least a portion of the first chip 100, at least a portion of the bridge die 150, and at least a portion of the second chip 200 may overlap in the first direction D1. Because a region in which the at least a portion of the first chip 100, the at least a portion of the bridge die 150, and the at least a portion of the second chip 200 overlap in the first direction D1 is present, a length of a wiring that connects the first chip 100 and the second chip 200 through the bridge die 150 may be decreased. Thus, a speed of electrical signal exchange between the first chip 100 and the second chip 200 may be improved. Also, because the at least a portion of the first chip 100, the at least a portion of the bridge die 150, and the at least a portion of the second chip 200 overlap in the first direction D1, a size of the semiconductor package which includes the first chip 100, the bridge die 150, and the second chip 200 may be reduced.

According to some example embodiments, the wiring post 250 may be extending in the first direction D1 between the second semiconductor chip 200 and the redistribution substrate 50. The wiring post 250 may be disposed on the redistribution substrate 50 in the first direction D1. More specifically, the wiring post 250 may be disposed below the second chip 200 in the first direction D1. The wiring post 250 may electrically connect the second chip 200 and the redistribution substrate 50.

According to some example embodiments, the wiring post 250 may be disposed to be spaced apart from the first chip 100 and the bridge die 150 in the second direction D2. The wiring post 250 may overlap the first chip 100 and the bridge die 150 in the second direction D2.

According to some example embodiments, the wiring post 250 may be disposed on the redistribution structure 52 of the redistribution substrate 50. For example, a connection pad connected to the redistribution structure 52 may be disposed on the redistribution substrate 50, and the wiring post 250 may be disposed on the connection pad. In the first direction D1, the wiring post 250 may be disposed below the lower connection pad 202 which is exposed from the lower surface of the second chip 200. The wiring post 250 may be disposed between the lower connection pad 202 and the redistribution substrate 50. The wiring post 250 may electrically connect the second chip 200 and the redistribution substrate 50 by connecting the lower connection pad 202 and the redistribution structure 52.

According to some example embodiments, the wiring post 250 may penetrate the first molding film 410. The wiring post 250 may be surrounded by the first molding film 410. A side wall of the wiring post 250 may be covered with the first molding film 410.

According to some example embodiments, the wiring post 250 may include a metallic material such as titanium (Ti), copper (Cu), aluminum (Al), silver (Ag), tin (Sn), gold (Au), nickel (Ni), lead (Pb), and/or an alloy thereof. FIGS. 1 and 2 illustrate examples in which the wiring post 250 is a single film. For example, the wiring post 250 may include a multilayered film structure.

According to some example embodiments, the connection die 350 may be disposed on the semiconductor chip 100. An upper surface of the connection die 350 and the upper surface of the bridge die 150 may be disposed on an identical plane based on the upper surface of the redistribution substrate 50. A lower surface of the connection die 350 and the lower surface of the bridge die 150 may be disposed on an identical plane based on the upper surface of the redistribution substrate 50. A side surface of the connection die 350 may be surrounded by the first molding film 410. According to example embodiments, the connection die 350 may include silicon (Si). The connection die 350 may include a portion of a circuit of the first chip 100.

According to some example embodiments, the thermal conductivity of the connection die 350 may be greater than the thermal conductivity of the connection die 150. Thus, with respect to heat generated in the first chip 100, an amount transferred to the bridge die 150 may larger than an amount transferred to the connection die 350. Thus, transfer of the heat generated in the first chip 100 to the second chip 200 may be suppressed. The heat generated in the first chip 100 may be transferred to the dummy die 300 through the connection die 350.

According to some example embodiments, the dummy die 300 may be disposed on the connection die 350. The dummy die 300 may be spaced apart from the second chip 200 in the second direction D2. The dummy die 300 may emit heat transferred from the first chip 100 through the connection die 350. According to an example, the dummy die 300 may include silicon (Si). According to an example, the dummy die 300 may include a material having a heat emission property.

According to some example embodiments, the first molding film 410 may surround the first chip 100, the connection die 350, the bridge die 150, and the wiring post 250 on the redistribution substrate 50. The first molding film 410 may cover side surfaces of the first chip 100, the connection die 350, the bridge die 150, and the wiring post 250. The second molding film 420 may surround the dummy die 300 and the second chip 200 on the first molding film 410. The second molding film 420 may cover side surfaces of the dummy die 300 and the second chip 200. The first molding film 410 and the second molding film 420 may include, for example, a polymer such as a resin. For example, the first molding film 410 and the second molding film 420 may include an epoxy molding compound (EMC).

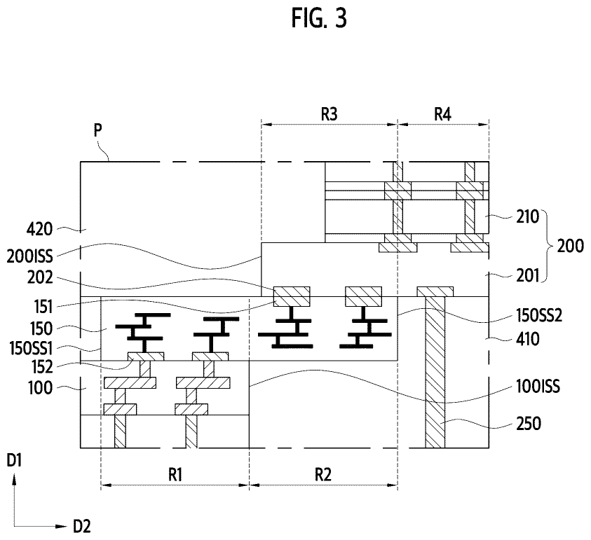

FIG. 3 is an example diagram illustrating an enlargement of portion P of FIG. 1 in order to describe a semiconductor package according to some other example embodiments. In order to describe the semiconductor package according to some other example embodiments, a description will mainly focus on a point different from that described above with reference to FIGS. 1 through 2.

Referring to FIG. 3, the first region R1 of the bridge die 150 and the third region R3 of the second chip 200 may not overlap in the first direction D1. The inward side surface 100ISS of a first chip may not overlap the second chip 200 in the first direction D1. The inward side surface 200ISS of a second chip may not overlap the first chip 100 in the first direction D1. A width of the third region R3 in the second direction D2 may be smaller than a width of the second region R2.

According to some example embodiments, the first chip 100 and the second chip 200 may not overlap in the first direction D1. The first chip 100 and the second chip 200 which do not overlap each other in the first direction D1 may be electrically connected to each other through the bridge die 150 which is disposed over the first chip 100 and the second chip 200. Because the first chip 100 and the second chip 200 do not overlap each other in the first direction D1, transfer of heat generated in the first chip 100 to the second chip 200 may be reduced.

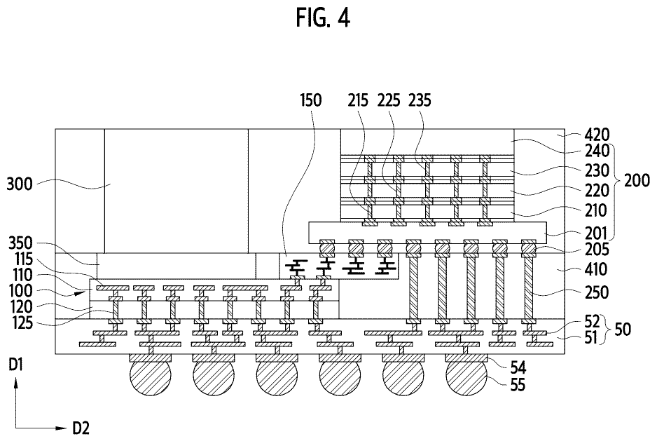

FIG. 4 is an example diagram illustrating a cross section of a semiconductor package according to still some other example embodiments. In order to describe the semiconductor package according to still some other example embodiments, a description will mainly focus on a point different from that described above with reference to FIGS. 1 and 2.

Referring to FIG. 4, the semiconductor package according to still some other example embodiments may include a connection bump 205 disposed below the second chip 200. The connection bump 205 may be disposed on a connection pad in contact with the wiring post 250 and the upper bridge connection pad 151 (of FIG. 2) which is connected to a wiring structure of the bridge die 150. The second chip 200 may be connected to the bridge die 150 and the wiring post 250 through the connection bump 205. The second chip 200 may be connected to the bridge die 150 through the connection bump 205 in a flip-chip bonding scheme.

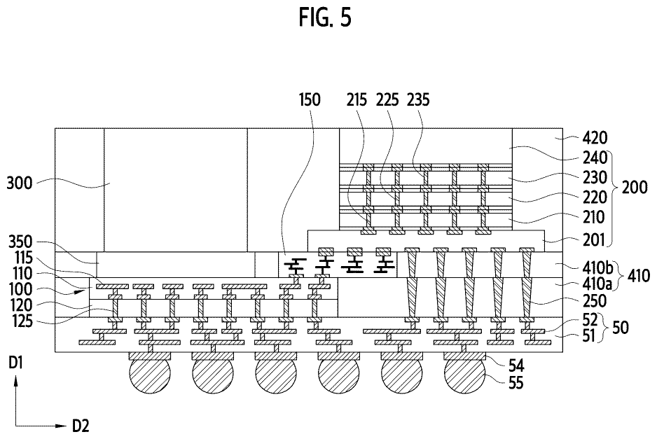

FIG. 5 is an example diagram illustrating a cross section of a semiconductor package according to still some other example embodiments. In order to describe the semiconductor package according to still some other example embodiments, a description will mainly focus on a point different from that described above with reference to FIGS. 1 and 2.

Referring to FIG. 5, the first molding film 410 may have a multilayered film structure. The first molding film 410 may include a first sub-molding film 410a and a second sub-molding film 410b. The first sub-molding film 410a and the second sub-molding film 410b may be disposed in the first direction D1. The second sub-molding film 410b may be disposed on the first sub-molding film 410a. The first sub-molding film 410a may surround a side surface of the first chip 100 and at least a portion of the wiring post 250. The second sub-molding film 410b may surround a side surface of the connection die 150, a side surface of the bridge die 150, and at least a portion of the wiring post 250.

According to some example embodiments, the wiring post 250 may have a step between the first sub-molding film 410a and the second sub-molding film 410b. The wiring post 250 may penetrate the first sub-molding film 410a and the second sub-molding film 410b.

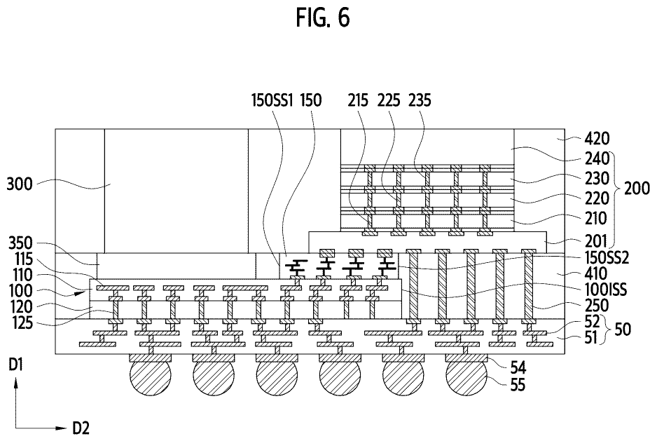

FIG. 6 is an example diagram illustrating a cross section of a semiconductor package according to some example embodiments. In order to describe the semiconductor package according to still some other example embodiments, a description will mainly focus on a point different from that described above with reference to FIGS. 1 and 2.

Referring to FIG. 6, a region of the bridge die 150 may overlap the first chip 100 in the first direction D1. The second side surface 150SS2 of the bridge die 150 may overlap the first chip 100. In the second direction D2, the second side surface 150SS2 of the bridge die 150 may be disposed to be adjacent to the first side surface 150SS2 of the bridge die 150 further than the inward side surface 100ISS of the first chip is. Because the entire region of the bridge die 150 overlaps the first chip 100 in the first direction D1, a speed of signal transfer between the first chip 100 and the second chip 200 through the bridge die 150 may be further improved.

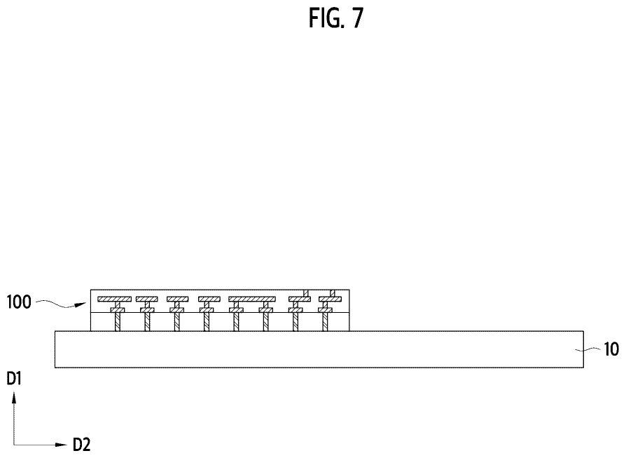

FIGS. 7 through 10 are example diagrams illustrating an intermediate operation for describing a method for fabricating a semiconductor package according to some example embodiments, which is illustrated in FIG. 1.

Referring to FIG. 7, the first chip 100 may be formed on a carrier substrate 10. The carrier substrate 10 may be an insulation substrate including glass or a polymer or may be a conductive substrate including a metal. The carrier substrate 10 may be a support substrate to which the first chip 100 is arbitrarily formed in a process of fabricating the semiconductor package.

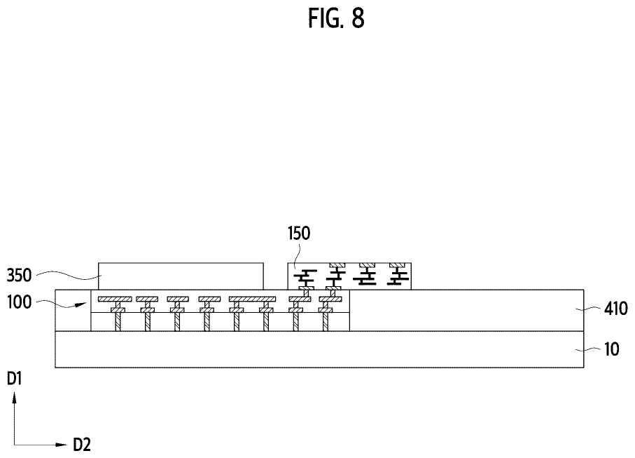

Referring to FIG. 8, the first molding film 410 which surrounds the first chip 100, and the connection die 350 and the bridge die 150 may be formed on the first chip 100.

According to some example embodiments, the first molding film 410 may surround a side surface of the first chip 100. The connection die 350 and the bridge die 150 may be connected to the first die 100 by a hybrid bonding scheme. The connection die 350 and the bridge die 150 may be formed on the first molding film 410.

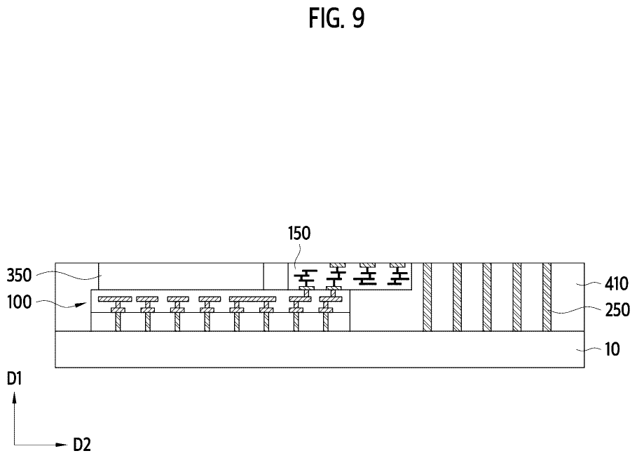

Referring to FIG. 9, the first molding film 410 which surrounds the connection die 350 and the bridge die 150 may be formed, and the wiring post 250 which penetrates the first molding film 410 may be formed. The first molding film 410 may be formed to cover the connection die 350 and the bridge die 150. The wiring post 250 may be formed in the first molding film 410.

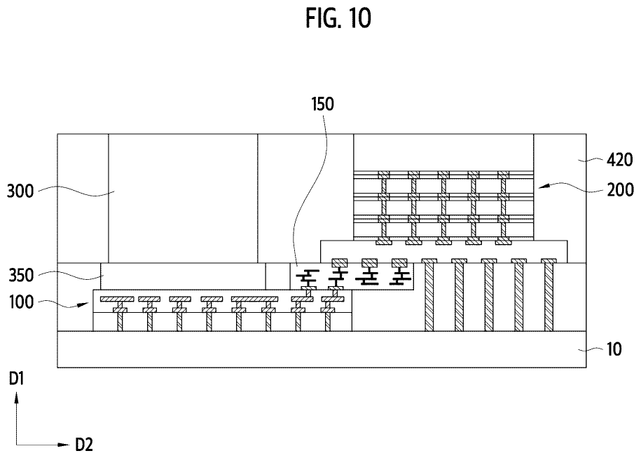

Referring to FIG. 10, the dummy die 300, the second chip 200, and the second molding film 420 may be formed. The dummy die 300 may be formed on the connection die 350. The second chip 200 may be formed on the bridge die 150 and the wiring post 250. The second chip 200 may be connected to the bridge die 150 by a hybrid bonding scheme. The second molding film 420 may be formed to surround the dummy die 300 and the second chip 200 on the first molding film 410.

Then, referring to FIG. 1, the carrier substrate 10 (of FIG. 10) may be removed, and the redistribution substrate 50 which is connected to the first chip 100 and the wiring post 250 may be formed.

The various example embodiments of the present invention have been described above in detail, but the scope of the present disclosure is not limited thereto. It will be apparent to those skilled in the art that various changes and modifications may be allowed within the range of the technical spirit of the present disclosure. In addition, the above-described example embodiments may be implemented without a portion of elements thereof, and each of the example embodiments may be implemented in combination with another.

According to example embodiments, it is possible to miniaturize a semiconductor package.

According to example embodiments, it is possible to improve reliability of a semiconductor package.

What is claimed is:

1. A semiconductor package comprising:
a redistribution substrate;
a first chip disposed on an upper surface of the redistribution substrate in a first direction;
a bridge die having an upper surface and a lower surface, the lower surface of the bridge die being disposed on the first chip in the first direction, the upper surface of the bridge die being opposite the lower surface; and
a second chip disposed on the upper surface of the bridge die in the first direction,
wherein the bridge die comprises:
a first region overlapping the first chip in the first direction; and
a second region that does not overlap the first chip in the first direction.

2. The semiconductor package of claim 1, further comprising a wiring post extending in the first direction connecting the second chip and the redistribution substrate.

3. The semiconductor package of claim 2, further comprising a first molding film surrounding the first chip, the bridge die and the wiring post.

4. The semiconductor package of claim 2, wherein the wiring post overlaps the first chip and the bridge die in a second direction, the second direction crossing the first direction.

5. The semiconductor package of claim 1, wherein the second chip comprises:
a third region overlapping the bridge die in the first direction; and
a fourth region that does not overlap the bridge die in the first direction.

6. The semiconductor package of claim 5, wherein at least a portion of the first region and at least a portion of the third region overlap each other in the first direction.

7. The semiconductor package of claim 5, wherein, in a second direction crossing the first direction, a width of the third region is smaller than a width of the fourth region.

8. The semiconductor package of claim 1, further comprising a dummy die disposed above the first chip in the first direction and disposed to be spaced apart from the second chip in a second direction crossing the first direction.

9. The semiconductor package of claim 8, further comprising a connection die disposed between the first chip and the dummy die in the first direction, the connection die being spaced apart from the bridge die in the second direction.

10. The semiconductor package of claim 9, wherein a thermal conductivity of the bridge die is lower than a thermal conductivity of the connection die.

11. The semiconductor package of claim 8, further comprising a second molding film surrounding the dummy die and the second chip.

12. The semiconductor package of claim 1, wherein the bridge die comprises an upper bridge connection pad facing the second chip, and
the second chip comprises a lower connection pad in contact with the upper bridge connection pad.

13. The semiconductor package of claim 1, further comprising a connection bump disposed between the bridge die and the second chip and connecting the bridge die and the second chip.

14. The semiconductor package of claim 1, wherein the first chip comprises
a first through via electrically connecting the bridge die and the redistribution substrate, wherein the first through via penetrates at least a portion of the first chip in the first direction.

15. The semiconductor package of claim 1, wherein the second chip comprises:
a buffer die electrically connected to the bridge die; and
a plurality of memory dies disposed on the buffer die, wherein each memory die of the plurality of memory dies is connected to each other memory die of the plurality of memory dies through a second through via extending in the first direction through each memory die.

16. The semiconductor package of claim 1, wherein
the first chip includes a logic chip, and
the second chip includes a memory chip.

17. A semiconductor package comprising:
a redistribution substrate;
a first chip disposed on an upper surface of the redistribution substrate in a first direction;
a bridge die having an upper surface and a lower surface, the lower surface of the bridge die being disposed on the first chip in the first direction, the upper surface of the bridge die being opposite the lower surface; and
a second chip disposed on the upper surface of the bridge die in the first direction,
wherein at least a portion of the first chip and at least a portion of the second chip overlap each other in the first direction.

18. The semiconductor package of claim 17, wherein the first chip, the bridge die, and the second chip are each disposed to be offset from each other in a second direction crossing the first direction.

19. The semiconductor package of claim 17, wherein an entire region of the bridge die overlaps the first chip in the first direction.

20. A semiconductor package comprising:
a redistribution substrate;
a first chip disposed on an upper surface of the redistribution substrate in a first direction;
a bridge die having an upper surface and a lower surface, the lower surface of the bridge die being disposed on the first chip in the first direction, the upper surface of the bridge die being opposite the lower surface;
a second chip disposed on the upper surface of the bridge die in the first direction;
a connection die on the first chip in the first direction, wherein the connection die is spaced apart from the bridge die in a second direction crossing the first direction; and
a dummy die spaced apart from the second chip in the second direction, wherein the dummy die is on the connection die,
wherein at least a portion of the first chip, at least a portion of the bridge die, and at least a portion of the second chip overlap each other in the first direction,
an upper surface of the connection die and the upper surface of the bridge die are disposed on an identical plane,
the first chip includes a logic chip, and
the second chip includes a memory chip.
